(19) United States
(12) Patent Application Publication
(10) Pub. No.: US 2026/0026291 A1
(43) Pub. Date: Jan. 22, 2026

(54) SUBSTRATE PROCESSING APPARATUS INCLUDING TEMPERATURE SENSOR

(71) Applicant: KWANGWOON UNIVERSITY INDUSTRY-ACADEMIC COLLABORATION FOUNDATION, Seoul (KR)

(72) Inventors: Gi Chung KWON, Seongnam-si (KR); Jae Hyeon KIM, Seoul (KR); Ji Hwan KIM, Seoul (KR); Seong Yong LIM, Gwangmyeong-si (KR); Hyeon Jo KIM, Seoul (KR)

(73) Assignee: KWANGWOON UNIVERSITY INDUSTRY-ACADEMIC COLLABORATION FOUNDATION, Seoul (KR)

(21) Appl. No.: 19/241,573

(22) Filed: Jun. 18, 2025

(30) Foreign Application Priority Data
Jul. 17, 2024 (KR) 10-2024-0094470

(51) Int. Cl. H01L 21/67; H01L 21/683

(52) U.S. Cl. CPC H01L 21/67248; H01L 21/67103; H01L 21/6833

(57) ABSTRACT

A substrate processing apparatus including a temperature sensor according to the present disclosure includes a substrate holder which fixes a substrate by an electrostatic force and a body unit which is disposed below the substrate holder and includes a thermal conductivity adjustment channel which adjusts a thermal conductivity based on a pressure formed by a thermal conductivity adjustment gas. A fiber Bragg grating (FBG) temperature is installed in the substrate holder and the FBG temperature sensor is installed in a hollow formed in the substrate holder.

### BACKGROUND

### Field

The present disclosure relates to a substrate processing apparatus, and more particularly, to a substrate processing apparatus including a temperature sensor.

### Description of the Related Art

As the performance of semiconductor device improves, the difficulty of manufacturing processes, such as miniaturization, three-dimensional structures, and high aspect ratios, increases so that in order to ensure the stable device performance and the high yield, it is important to ensure the process uniformity.

In the case of the substrate temperature, which is one of important elements of the process uniformity, the uniform substrate temperature distribution is maintained using an electrostatic chuck (ESC) in the substrate processing apparatus.

The electrostatic chuck allows a substrate to be supported above the electrostatic chuck using an electrostatic force formed by applying a voltage to a chucking electrode formed therein. The temperature of the electrostatic chuck is adjusted by a heater and a coolant channel formed in the electrostatic chuck and the temperature of the substrate is controlled by injecting a gas with a high thermal conductivity between the substrate and the electrostatic chuck. The temperature of the electrostatic chuck and the substrate is required to be maintained and controlled at an extremely low temperature below 0° C., a low temperature between 0° C. and 200° C., or a high temperature above 200° C., depending on the manufacturing process.

The thermal conductivity between the electrostatic chuck and the substrate may vary locally, according to the coolant channel, the heater, the chucking electrode, or a hole pattern of the electrostatic chuck. In order to improve the temperature uniformity of the substrate, the electrostatic chuck adjusts the patterns of the coolant flow path, the heater, or the chucking electrode. Further, in order to improve the temperature uniformity, the electrostatic chuck individually controls the temperature of areas which is divided into two, four or more areas to form a heater or a coolant channel of multi zones.

In the related art, the process processing apparatus uses a temperature measurement system configured by a temperature sensor using an electric signal, such as a thermocouple (TC) or a resistive temperature detector (RTD) and a temperature sensor using an optical signal, such as a light probe temperature sensor in the electrostatic chuck to measure a substrate temperature during the semiconductor manufacturing process. The TC and RTD temperature sensors measure a temperature range of −200° C. or lower or 800° C. or higher and have a small size to be installed in a specific position or multiple zones of the electrostatic chuck to measure a temperature real time. However, the TC and RTD temperature sensors may have difficulty to accurately measure a temperature due to signal interference caused by electromagnetic waves, such as plasma. In contrasts, the optical probe temperature sensor has an advantage of measuring the temperature without the signal interference due to the electromagnetic wave, but when the probe type temperature sensor is used, there is a spatial limitation in installing the temperature sensor when a specific position below the electrostatic chuck.

The substrate processing device includes a focus ring which encloses the electrostatic chuck and an outer circumference of the substrate to improve the process uniformity during the semiconductor manufacturing process using plasma. The focus ring adjusts the electric field distribution at the edge of the substrate during the process with its structure to improve the plasma uniformity. Not only the electrical characteristic, but also the temperature of the focus ring affects the process uniformity, such as polymer deposition or process byproduct deposition on the substrate edge or the focus ring. The temperature of the focus ring is set to be higher than or lower than a temperature of the substrate according to the performed process by installing the heater in the focus ring or a structure below the focus ring or injecting the coolant to improve the process yield.

When the semiconductor manufacturing process is performed, in an environment in which a heat source, such as light or plasma is present, a temperature change rate at every position of the substrate and the focus ring may vary depending on the power of the heat source, a uniformity of the heat source, the plasma density, and a shape of the plasma sheath. Accordingly, when the temperature measurement system of the related art is used, it is difficult to precisely measure and calculate the temperature uniformity of the substrate and the focus ring and there may be a limitation in improving the process uniformity by controlling the temperature of the substrate and the focus ring.

### SUMMARY

An object to be achieved by the present disclosure is to provide a substrate processing apparatus including a temperature sensor which measures the temperature and the temperature uniformity of the substrate or the focus ring in the substrate processing apparatus using a fiber Bragg grating (FBG) temperature sensor in real time during the process. The FBG temperature sensor includes a plurality of temperature sensors formed in one optical fiber and measures a temperature of a plurality of locations using an optical signal without being affected by an electrical noise.

The technical object to be achieved by the present disclosure is not limited to the above-mentioned technical objects, and other technical objects, which are not mentioned above, can be clearly understood by those skilled in the art from the following descriptions.

In order to achieve the above-described technical object, according to an aspect of the present disclosure, a substrate processing apparatus including a temperature sensor includes a substrate holder which fixes a substrate by an electrostatic force and a body unit which is disposed below the substrate holder and includes a thermal conductivity adjustment channel which adjusts a thermal conductivity based on a pressure formed by a thermal conductivity adjustment gas, and a fiber Bragg grating (FBG) temperature is installed in the substrate holder and the FBG temperature sensor is installed in a hollow formed in the substrate holder.

A width and a height of the hollow are formed to be larger than a diameter of the FBG temperature sensor.

The FBG temperature sensor is installed so as to be in contact with at least one inner surface of the hollow.

A cross-section of the hollow includes a V-shaped groove and the FBG temperature sensor is installed so as to be in contact with both inclined surfaces of the V-shaped groove.

An end portion of the FBG temperature sensor is fixed to a bottom surface of the hollow and the FBG temperature sensor is installed to be curved in the hollow and a measurement part of the FBG temperature sensor is installed to be in contact with a top surface of the hollow.

A thermal conductive paste or epoxy is filled in the hollow.

A thermal conductivity adjustment gas is injected into the hollow.

The substrate processing apparatus further includes a focus ring disposed on an outer periphery of the substrate holder, a fiber Bragg grating (FBG) temperature is installed in the focus ring and the FBG temperature sensor is installed in a hollow formed in the focus ring.

The FBG temperature sensor installed in the focus ring is installed at every distance from the substrate.

In order to achieve the above-described technical object, according to another aspect of the present disclosure, a substrate processing apparatus including a temperature sensor includes a substrate holder which fixes a substrate by an electrostatic force and a body unit which is disposed below the substrate holder and includes a thermal conductivity adjustment channel which adjusts a thermal conductivity based on a pressure formed by a thermal conductivity adjustment gas, and a fiber Bragg grating (FBG) temperature is installed in the body unit and the FBG temperature sensor is installed in a hollow formed in the body unit.

According to the present disclosure described above, the substrate processing device includes a temperature sensor which measures the temperature and the temperature uniformity of the substrate or the focus ring in the substrate processing apparatus using the FBG temperature sensor, in real time during the process. The FBG temperature sensor includes a plurality of temperature sensors formed in one optical fiber and measures a temperature of a plurality of locations using an optical signal without being affected by an electrical noise.

The technical object to be achieved by the present disclosure is not limited to the above-mentioned technical objects, and other technical objects, which are not mentioned above, can be clearly understood by those skilled in the art from the following descriptions.

### BRIEF DESCRIPTION OF DRAWINGS

FIG. 1 illustrates a cross-sectional configuration of a substrate processing apparatus according to an exemplary embodiment of the present disclosure;

FIG. 2 illustrates an example of a configuration of an FBG temperature sensor;

FIG. 3 illustrates a temperature measurement principle of an FBG temperature sensor;

FIG. 4 illustrates an example of a multi-zone heater pattern of a substrate holder;

FIG. 5 illustrates an example of a pattern in which an FBG temperature sensor is installed in a substrate holder having a multi-zone heater pattern;

FIG. 6 illustrates an example of a cross-section of a hollow in which an FBG temperature sensor is installed;

FIG. 7 illustrates another example of a cross-section of a hollow in which an FBG temperature sensor is installed;

FIG. 8 illustrates still another example of a cross-section of a hollow in which an FBG temperature sensor is installed;

FIG. 9 illustrates an example of a cross-section along a path of a hollow in which an FBG temperature sensor is installed;

FIG. 10 illustrates an example of a cross-section of a focus ring in which an FBG temperature sensor is installed;

FIG. 11 illustrates another example of a cross-section of a focus ring in which an FBG temperature sensor is installed;

FIG. 12 illustrates an example of a structure in which an FBG temperature sensor is installed for every distance from a substrate in a focus ring;

FIG. 13 illustrates a cross-sectional configuration of a body unit when an FBG temperature sensor is installed in a body unit of an electrostatic chuck; and

FIG. 14 is a graph obtained by comparing a measurement temperature of an FBG temperature sensor and a measurement temperature of a TC temperature sensor.

### DETAILED DESCRIPTION OF THE EMBODIMENT

Hereinafter, exemplary embodiments of the present disclosure will be described in detail with reference to the drawings. Substantially same components in the following description and the accompanying drawings may be denoted by the same reference numerals so that a redundant description will be omitted. Further, in the description of the exemplary embodiment, if it is considered that specific description of related known configuration or function may cloud the gist of the present disclosure, the detailed description thereof will be omitted.

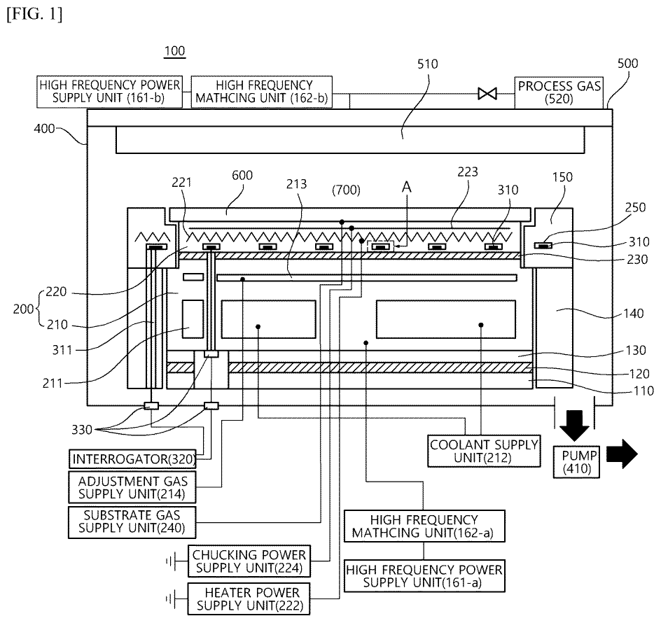

FIG. 1 illustrates a cross-sectional configuration of a substrate processing apparatus according to an exemplary embodiment of the present disclosure;

A substrate processing apparatus 100 according to an exemplary embodiment of the present disclosure may be a substrate processing apparatus which performs a cryogenic process in an extremely low temperature range. The cryogenic process may be cryogenic etching or cryogenic atomic layer etching. Here, the ultra-low temperature range is 0° C. or lower and desirably −40° C. or lower.

The substrate processing apparatus 100 includes a chamber 400, a first support 110, an insulating layer 120, a base 130, an electrostatic chuck 200, a second support 140, a focus ring 150, a shower head 510, and a lead 500.

The substrate processing apparatus 100 supports the substrate 6 above the electrostatic chuck 200 by electrostatic force and controls the temperature and the temperature uniformity of the substrate 600. A diameter of the substrate 600 may be 200 mm or 300 mm and the substrate 600 may be a wafer or glass. The electrostatic chuck 200 may be configured by a body unit 210 and a substrate holder 220 and is used as a lower electrode. The electrostatic chuck 200 may include one or a plurality of FBG temperature sensors 310 in the body unit 210 or the substrate holder 220.

The support holder 220 includes a heater electrode 221, a chucking electrode 223, and a gas supply flow path (not illustrated) and is attached to the body unit 210 by means of a bonding unit 230.

The body unit 210 is a metal material and includes a coolant channel 211 and a thermal conductivity adjustment channel 213.

The substrate processing apparatus 100 sets a desired vacuum level (for example, 10-6 Torr, 1 mTorr, or 1 Torr) in the chamber 400, through a pump 410 connected to the chamber 400 and an exhaust system (not illustrated).

The shower head 510 which is used as an upper electrode is formed in the lead 500 located above the chamber 400. If a process gas 520 is injected into a vacuum chamber 400 through the shower head 510, uniform gas distribution may be formed. After injecting the process gas, a high frequency wave is applied to the upper electrode or the lower electrode to discharge the plasma.

The substrate processing apparatus 100 according to the exemplary embodiment of the present disclosure represents a dry etching device using a capacitively coupled plasma source, but may also use an inductively coupled plasma (ICP) source, an electron cyclotron resonance (ECR) source, a remote plasma source (RPS), or a microwave source.

The substrate processing apparatus 100 according to the exemplary embodiment of the present disclosure represents an apparatus which is capable of performing a cryogenic process, but may also performs chemical vapor deposition (CVD), plasma enhanced chemical vapor deposition (PECVD), plasma etching, atomic layer deposition (ALD), or atomic layer etching (ALE) processes.

The insulating layer 120 electrically insulates the base 130 and the electrostatic chuck 200 from the first support 110 and insulates the first support 110 at the room temperature from the base 130 and the electrostatic chuck 200 at an extremely low temperature. The first support 110, the insulating layer 120, the base 130, and the electrostatic chuck 200 are mechanically coupled.

The electrostatic chuck 200 has a structure in which the body unit 210 and the support holder 220 are bonded by the bonding unit 230.

The support holder 220 is configured by a dielectric material, such as aluminum oxide (Al₂O₃) or aluminum nitride (AlN) which is capable of performing the cryogenic process and has an electrostatic force of Coulomb force or Johnson-Rahbek force depending on a resistivity of the support holder 220.

If the resistivity of the substrate holder 200 is 10¹⁴ Ω·cm or 10¹⁶ Ω·cm or higher, when a direct current (DC) or alternative current (AC) power is applied to the chucking electrode 223 through the chucking power supply unit 224, the Coulomb force is generated to support the substrate. If the resistivity is 10¹² Ω·cm or 10¹⁰ Ω·cm or lower, when a direct current (DC) or alternative current (AC) power is applied to the chucking electrode 223 through the chucking power supply unit 224, the Johnson-Rahbek force is generated to support the substrate. When the resistivity is in the range of 10¹⁴ Ω·cm or 10¹⁶ Ω·cm or 10¹² Ω·cm or 10¹⁰ Ω·cm, the electrostatic force may be a mixed form of the Coulomb force and the Johnson-Rahbek force.

The substrate holder 220 may be configured by a material having a resistivity of 10¹² Ω·cm or 10¹⁰ Ω·cm, in consideration of the change in the resistivity in accordance with the temperature change to perform the cryogenic process.

The heater electrode 221 and the chucking electrode 223 are buried in the substrate holder 220.

The chucking electrode 223 is formed with a specific pattern and may be configured by a mono-pole, a bi-pole, or multi-pole.

The chucking electrode 223 is configured by a material which is determined in consideration of an electric conductivity and a coefficient of thermal expansion of a dielectric material which configures the substrate holder 220. For example, the chucking electrode 223 may be configured by tungsten (W) or molybdenum (Mo) by considering that a coefficient of thermal expansion of Al₂O₃ is 7*10⁻⁶/K to 8*10⁻⁶/K and a coefficient of thermal expansion of AlN is 4*10⁻⁶/K to 5*10⁻⁶/K.

The heater electrode 221 is buried in the substrate holder 220 and is formed with a specific pattern and has a pattern configured by a single zone or multi zones.

The heater electrode 221 is configured by a material, such as tungsten (W) or molybdenum (Mo) or alloy including metal by considering the coefficient of expansion or electric conductivity to perform the cryogenic process.

The heater electrode 221 is electrically connected to the heater power supply unit 222 configured by a filter, a DC or AC power supply device. In the case of the multi-zone heater, a plurality of DC or AC powers may be connected.

Further, the substrate holder 200 supplies a substrate gas to an empty space between the substrate holder 220 and the substrate through the substrate gas supply unit 240 which is a gas supply flow passage (not illustrated) formed in the substrate holder 220. Here, the substrate gas may be helium (He) or nitrogen (N₂), and desirably, may be a helium (He).

The body unit 210 may be configured by a metal based material (for example, Al, Ti, or Mo) which is determined in consideration of the coefficient of thermal expansion (CTE) of the substrate holder 220 to perform smooth cryogenic process in the extremely-low temperature range. For example, when the substrate holder 220 is configured by Al₂O₃, the body unit 210 may be configured by metal matrix composite (MMC) configured by Al—SiC or Al—Si by considering that the coefficient of thermal expansion of Al₂O₃ is 7*10⁻⁶/K˜8*10⁻⁶/K. In the case of Al—SiC, the higher a Sic content (SiC wt %), the lower the coefficient of thermal expansion. Accordingly, in the case of the body unit 210 configured by Al—SiC, the coefficient of thermal expansion matches the coefficient of thermal expansion of the substrate holder 220 by adjusting the SiC wt %. In the case of the body unit 210 configured by Al—SiC, the SiC content range may be 15 wt % to 85 wt %, and desirably may be 65 wt % to 85 wt %. The coefficient of thermal expansion of Al-70% SiC is 7*10⁻⁶/K, so that the coefficient of thermal expansion matches with the coefficient of thermal expansion of the substrate holder 220 configured by Al₂O₃.

A diameter of the body unit 210 may be equal to or larger than the diameter of the substrate 600. For example, when the diameter of the substrate 600 is 300 mm, the diameter of the body unit 210 may be 300 mm or larger (for example, 310 mm to 340 mm).

The body unit 210 includes a coolant channel 211 and a thermal conductivity adjustment channel 213.

The body unit 210 supplies coolant to the coolant channel 211 formed in the body unit 210 through the coolant supply unit 212 such as a chiller, a liquid nitrogen (LN₂) circulation system, or LN₂ Dewar to adjust the temperature and a temperature uniformity of the substrate holder 220 and the substrate 600. The coolant may be hydrofluoroether (HFE), galden, or liquid nitrogen (LN₂).

The thermal conductivity adjustment channel 213 may be formed above the coolant channel 211.

The thermal conductivity adjustment channel 213 adjusts the thermal conductivity with a pressure formed by supplying a thermal conductivity adjustment gas therein through the adjusted gas supply unit 214. The thermal conductivity adjustment channel 213 adjusts the thermal conductivity according to a thermal conductivity adjustment gas (for example, He or N₂), an internal pressure (for example, 10 mTorr or lower, 100 mTorr, 1 Torr, 10 Torr, 100 Torr or higher) formed with the thermal conductivity adjustment gas, or a thermal conductivity adjustment gas flow rate.

Here, as the internal pressure of the thermal conductivity adjustment channel 213 is close to 0, the thermal conductivity becomes low. Further, the smaller the thickness of the thermal conductivity adjustment channel 213, the higher the thermal conductivity at the same pressure. A thickness of the thermal conductivity adjustment channel 213 is 1 mm or lower, and for example, 0.5 mm, 0.2 mm, 0.1 mm, or 0.05 mm or lower. Accordingly, the temperature and the temperature uniformity of the substrate holder 220 and the substrate 600 may be controlled by the thermal conductivity adjustment channel 213.

The thermal conductivity adjustment channel 213 is formed with a specific pattern and may be formed in a single zone or a plurality of zones. For example, when the heater electrode 221 of the substrate 220 is formed in a single zone, the thermal conductivity adjustment channel 213 is also formed in a single zone and when the heater electrode 221 of the substrate 220 is formed in multiple zones, the thermal conductivity adjustment channel 213 is also formed in a plurality of zones.

The focus ring 150 is disposed on an outer peripheral portion of the substrate holder 220 and is disposed on the second support 140.

The focus ring 150 may be configured by a dielectric material. For example, the focus ring is configured by Al₂O₃, AlN, yttrium oxide (Y₂O₃), yttrium oxyfluoride (YOF), silicon (Si), silicon carbide (SiC), or quartz. The focus ring 150 includes an FBG temperature sensor 310 therein and includes the heater electrode 221 and a cooling device (not illustrated) to adjust the temperature.

The high frequency power supply units 161a and 161b and the high frequency matching units 162a and 162b are electrically connected to the lead 500 used as an upper electrode or the electrostatic chuck 200 used as a lower electrode. The high frequency power supply units 161a and 161b and the high frequency matching units 162a and 162b generate plasma in a processing area 700.

Here, one or a plurality of high frequency power supply units 161a and 161b may be configured to process the substrate 600. For example, the high frequency power supply units 161a and 161b may be configured at lower than 13.56 MHZ (for example, 400 kHz) or 13.56 MHz or higher (for example, 13.56 MHz, 27.12 MHz, 40 MHz, 60 MHz, or 2.45 GHZ). When the plurality of high frequency power supply units 161a and 161b is provided, the high frequency matching units 162a and 162b are also plural.

The temperature measurement system (not illustrated) measures the temperature of the electrostatic chuck 200 and the focus ring by the FBC temperature sensor 310 installed in the electrostatic chuck 200 and the focus ring 150. The FBG temperature sensor has a structure in which a plurality of temperature sensors is formed in one optical fiber and measures a temperature of a plurality of locations using an optical signal without being affected by an electrical noise.

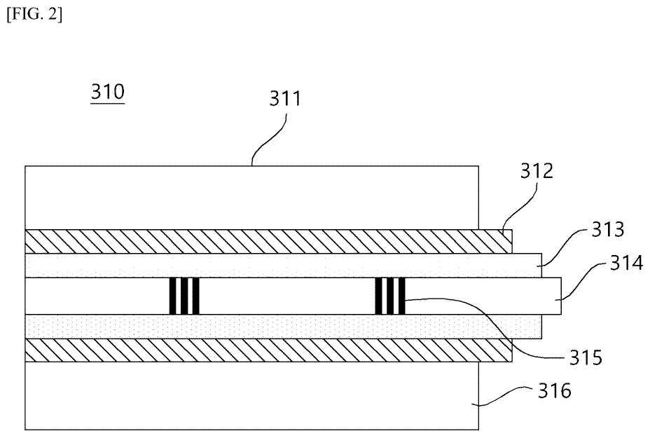

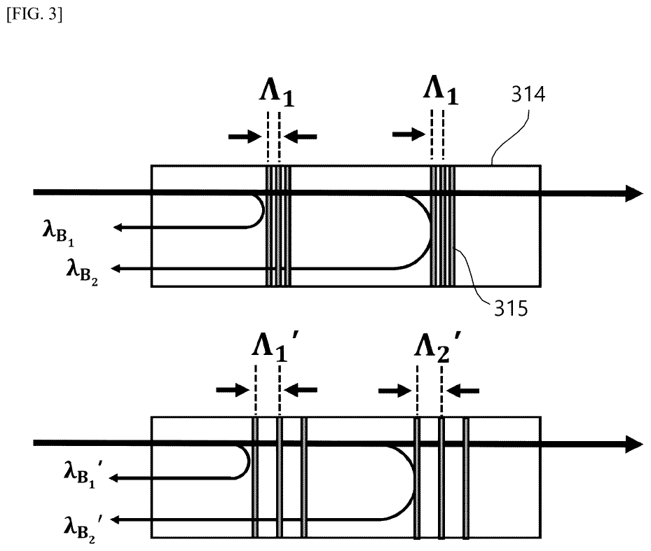

FIG. 2 illustrates an example of a configuration of an FBG temperature sensor and FIG. 3 illustrates a temperature measurement principle of an FBG temperature sensor.

The FBG temperature sensor 310 has a structure in which Bragg gratings 315 are formed in a core 314 of the optical fiber 311 and is configured by a core 314, a cladding 313, a coating 312, a protection layer, and Bragg gratings 315. When light is incident into the optical fiber 311, light corresponding to a Bragg wavelength is reflected according to a refractive index of each Bragg grating 315 and the remaining light passes through the Bragg grating 315. In the optical fiber 311, strain occurs due to thermal deformation, such as thermal contraction or thermal expansion according to the temperature change or other physical factor to change the refractive index of the grating and the Bragg wavelength.

A wavelength change rate according to a strain and a temperature change of the FBG temperature sensor is represented by the following Equation.

$${λ}_{B} = 2 {n}_{eff} Λ \\ {Δλ}_{B} = 2 ( Λ \frac{\partial {n}_{eff}}{\partial l} + {n}_{eff} \frac{\partial Λ}{\partial l} ) Δ l + 2 ( Λ \frac{\partial {n}_{eff}}{\partial T} + {n}_{eff} \frac{\partial Λ}{\partial T} ) Δ T \qquad [ Equation 1 ]$$

As represented in Equation, change of the reflected Bragg wavelength (Δλ_{B}) is represented by a strain Δl and a temperature change ΔT. The temperature change ΔT may be calculated by measuring the wavelength change (Δλ_{B}) of reflected light and the strain (Δl term).

The FBG temperature sensor 310 obtains a measured temperature of a plurality of locations by setting reflected light with a wavelength reflected from each grating 315 so as not to overlap the Bragg wavelength of light reflected from different grating 315 by varying the refractive index of each grating 315 in the optical fiber 311.

The FBG temperature sensor 310 forms 1 to 30 or more temperature sensors in one optical fiber 311 and determines a number of temperature sensors by considering the measured temperature range and a material of an optical fiber.

The FBG temperature sensor 310 is configured by an optical fiber formed of a material, such as silica or polymer and includes a protection layer 316 which protects the optical fiber.

A diameter of the optical fiber 311 which configures the FBG temperature sensor 310 may be 2 mm, 1.6 mm, 0.4 mm, 0.2 mm or smaller.

The optical fiber protection layer 316 is formed of a material, such as poly-ether-ether-ketone (PEEK), silica, stainless steel, or alumina. The thickness of the optical fiber protection layer 316 may be 5 mm or less (for example, 5 mm, 3 mm, 1 mm, or 0.4 mm) depending on the material and the wavelength change according to the temperature of the FBG temperature sensor 310 may vary depending on the material and the thickness of the optical fiber protection layer 316.

The FBG temperature sensor 310 includes the optical fiber protection layer 316 by considering a measurement temperature range, a number of temperature measurement locations, and a material of an object whose temperature is to be measured and the thickness and the material of the optical fiber protection layer 316 may be determined.

The FBG temperature sensor 310 is connected to an interrogator 320 at the outside of the chamber 400 through a feed-through 330 to calculate a physical change, such as a wavelength change or strain of the FBG temperature sensor 310 to measure the temperature.

Referring to FIG. 1, the FBG temperature sensor 310 is installed in a hollow 250 formed in the substrate holder 220 and is installed below the heater electrode 211. The FBG temperature sensor 310 is installed in the hollow 250 through the feed-through 330 connected to a lower portion of the body unit 210 and maintains an air-tight state in the hollow 250 by the feed-through 330.

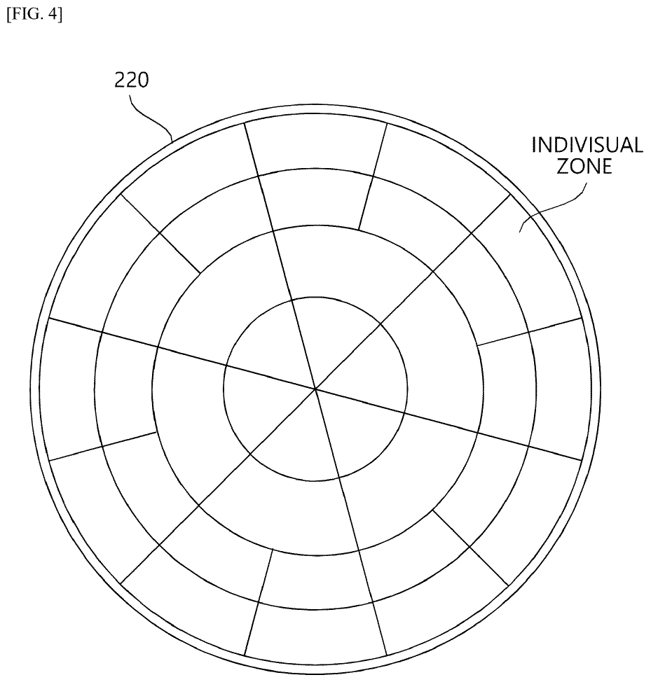

FIG. 4 illustrates an example of a multi-zone heater pattern of a substrate holder 200 and FIG. 5 illustrates an example of a pattern in which an FBG temperature sensor 310 is installed in a substrate holder 220 having a multi-zone heater pattern.

As illustrated in FIG. 4, the substrate holder 220 has a multi-zone heater pattern which is configured by a single zone or a plurality of individual zones. As illustrated in FIG. 5, in order to measure a temperature of the individual zone, a number and a position of measurement parts (Bragg grating) of the FBG temperature sensor 310 may be determined.

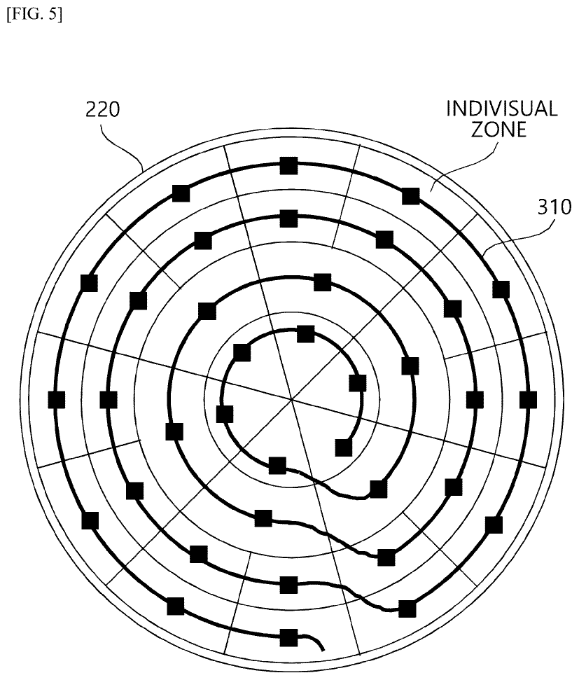

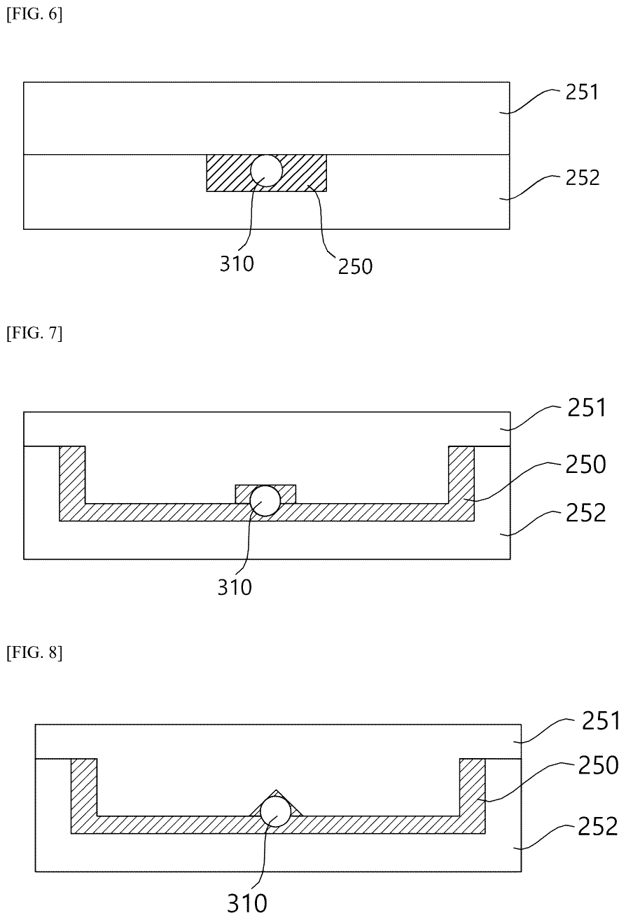

FIG. 6 illustrates an example of a cross-section of a hollow in which an FBG temperature sensor is installed, FIG. 7 illustrates another example of a cross-section of a hollow in which an FBG temperature sensor is installed, and FIG. 8 illustrates still another example of a cross-section of a hollow in which an FBG temperature sensor is installed.

FIGS. 6 to 8 are detailed views of the part “A” of FIG. 1 and illustrate an exemplary configuration for installing the FBG temperature sensor 310 in the hollow 250 formed in the substrate holder 220.

As illustrated in FIG. 6, the hollow 250 is configured by bonding a hollow upper layer 251 and a hollow lower layer 252 in which a groove is formed. The hollow 250 is formed with a specific pattern and a pattern of the hollow 250 is determined by considering a temperature measurement location of the substrate holder 220, the heater electrode 221, the chucking electrode 223, a hole location, and an optical fiber installation path.

In order to increase the thermal conductivity in the hollow 250, the FBG temperature sensor 310 may be in contact with at least one inner surface of the hollow 250. For example, the FBG temperature sensor 310 may be in contact with one or more surfaces of a side surface of the hollow 250, a bottom surface of the hollow upper layer 251, and a top surface of the hollow lower substrate 252.

For example, when the FBG temperature sensor 310 configured by an optical fiber 311 formed of silica material is installed in the substrate holder 220 configured by Al₂O₃, a width and a height of the hollow 250 are formed to be larger than the diameter of the FBG temperature sensor 310 by considering that the coefficient of thermal conductivity of Al₂O₃ is 7*10⁻⁶/K to 8*10⁻⁶/K and the coefficient of thermal conductivity of silica is 5*10⁻⁷K to 7*10⁻⁷K. In the case of the FBG temperature sensor 310 configured by silica, the diameter of the optical fiber is 0.1 mm to 0.2 mm so that the width and the height of the hollow 250 may be 0.3 mm or 0.5 mm or larger. The width and the height of the hollow 250 may vary depending on the material of the optical fiber 311 and the material of the optical fiber protection layer 316.

FIGS. 7 and 8 illustrate that a protruding portion and a groove are formed on the hollow upper portion 251 and the groove corresponding to the protruding portion is formed in the hollow lower portion 252 to form the hollow 250 by bonding the hollow upper portion 251 and the hollow lower portion 252.

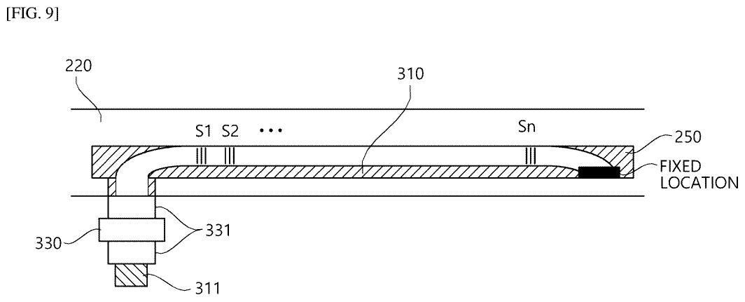

In FIG. 9, a V-shaped groove is formed in the hollow upper portion 251 so that the cross-section of the hollow 250 includes a V-shaped groove to allow the FBG temperature sensor to be in contact with both inclined surfaces of the V-shaped groove.

With the structure of FIG. 8, the contact points of the FBG temperature sensor 310 are increased as compared with the other structure to improve the thermal conductivity.

FIG. 9 illustrates an example of a cross-section along a path of a hollow in which an FBG temperature sensor is installed.

As illustrated in FIG. 9, the FBG temperature sensor 310 is installed in the hollow 250 such that an end portion of the FBG temperature sensor 310 is fixed to the bottom surface of the hollow 250. Further, the height of the hollow 250 is formed to be larger than the diameter of the FBG temperature sensor 310 and the length of the FBG temperature sensor 310 is adjusted so that the FBG temperature sensor 310 is convexly curved in the hollow 250 to have a spatial margin. Further, the measurement part (Bragg grating part, S1, S2, . . . , Sn) of the FBG temperature sensor 310 is in contact with the top surface of the hollow 250 to measure the temperature of the substrate holder 220. According to this structure, even though the substrate holder 220 is deformed according to the temperature, the measurement part of the FBG temperature sensor 310 is not fixed into the hollow 250 so that the strain deformation does not occur and the temperature change may be measured without causing the change of the Bragg wavelength due to the strain.

Referring to FIG. 9, the feed-through 330 includes an adaptor 331. The adaptor 331 is mechanically coupled to or separated from the FBG temperature sensor 310 installed in the hollow 250 and the optical fiber 311 below the feed-through 330. When a damage or an error occurs from the FBG temperature sensor 310 and the optical fiber 311, the FBG temperature sensor 310 and the optical fiber 311 are separated from the adaptor 311 to be replaced.

The hollow 250 is filled with thermal conductive paste or epoxy to increase the thermal conductivity of the hollow 250. When the filling material, such as the thermal conductive paste or the epoxy reaches the extremely low temperature, the viscosity is increased to increase the strain so that a material whose viscosity is relatively less changed at the extremely low temperature may be used.

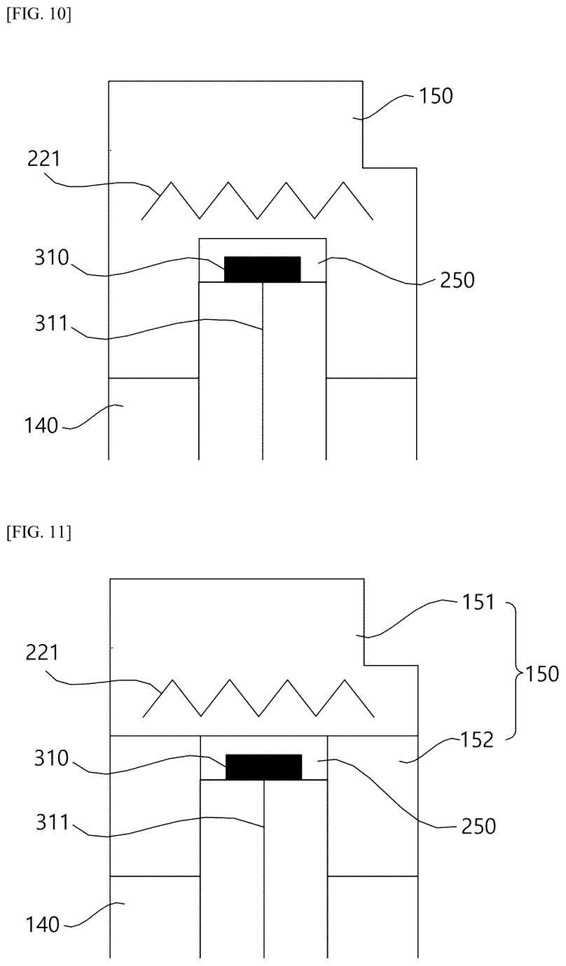

Further, the thermal conductivity of the hollow 250 may be increased by the pressure (for example, 100 Torr, 300 Torr, or 760 Torr) formed by injecting the thermal conductivity adjustment gas (for example, He or N₂) into the hollow 250. FIG. 10 illustrates an example of a cross-section of a focus ring in which an FBG temperature sensor is installed.

As illustrated in FIG. 10, the heater electrode 221 is buried in the focus ring 150 and the hollow 250 is formed therebelow to install the FBG temperature sensor 310 in the hollow 250.

The heater electrode 221 is connected to the heater power supply unit 222 to heat the focus ring 150 to a desired temperature.

The FBG temperature sensor 310 is also installed in the hollow 250 of the focus ring 150 by the structure which has been described above with reference to FIGS. 6 to 9. The hollow 250 is filled with thermal conductive paste or epoxy to increase the thermal conductivity of the hollow 250.

The FBG temperature sensor 310 in the focus ring 150 is connected to the optical fiber 311 through a through hole of the second support 140 and is connected to the interrogator 320 through the feed-through 330 of the chamber 400.

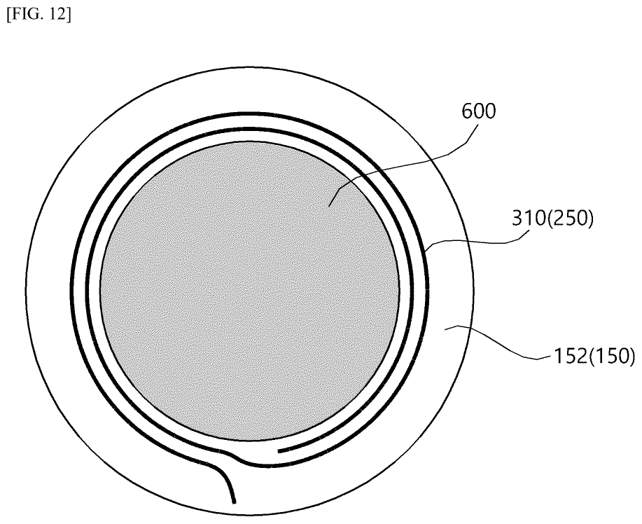

FIG. 11 illustrates another example of a cross-section of a focus ring in which an FBG temperature sensor is installed.

As illustrated in FIG. 11, the focus ring 150 is configured by an upper plate 151 and a lower plate 152.

The upper plate 151 includes the heater electrode 221 and the heater electrode 221 is connected to the heater power supply unit 222 to heat the upper plate 151 to a desired temperature.

The FBG temperature sensor 310 is installed in the groove (hollow) 250 formed on the lower plate 152 to be in contact with the bottom surface of the upper plate 151.

The FBG temperature sensor 310 is also installed in the hollow 250 of the focus ring 150 by the structure which has been described above with reference to FIGS. 6 to 9. The hollow 250 is filled with thermal conductive paste or epoxy to increase the thermal conductivity of the hollow 250.

The FBG temperature sensor 310 installed in the lower plate 152 is connected to the optical fiber 311 through a through hole of the second support 140 and is connected to the interrogator 320 through the feed-through 330 of the chamber 400.

FIG. 12 illustrates an example of a structure in which an FBG temperature sensor is installed for every distance from a substrate in a focus ring.

As illustrated in the drawing, the FBG temperature sensor 310 is installed in the groove 250 which is formed on the lower plate 152 of the focus ring 150 at every distance from the substrate 600. By doing this, the FBG temperature sensor 310 measures a temperature distribution of the focus ring 150 at every distance from the substrate 600. For example, the FBG temperature sensor 310 is formed in the groove 250 which is continuously formed along the periphery of the substrate 600 at a distance of approximately 3 mm and approximately 5 mm from the substrate 600, on the lower plate 152, to measure a temperature of the location of the focus ring 150 with a distance of approximately 3 mm and approximately 5 mm from the substrate 600. With this structure, when the FBG temperature sensor 310 is installed in the focus ring 150, the restriction for an installation space is minimized and the temperature uniformity of the overall focus ring 150 may be measured with one sensor.

According to the above-described exemplary embodiments of the present disclosure, the FBG temperature sensor 310 is installed in the substrate holder 220, but in some exemplary embodiment, the FBG temperature sensor 310 may be installed in the body unit 210, rather than the substrate holder 220.

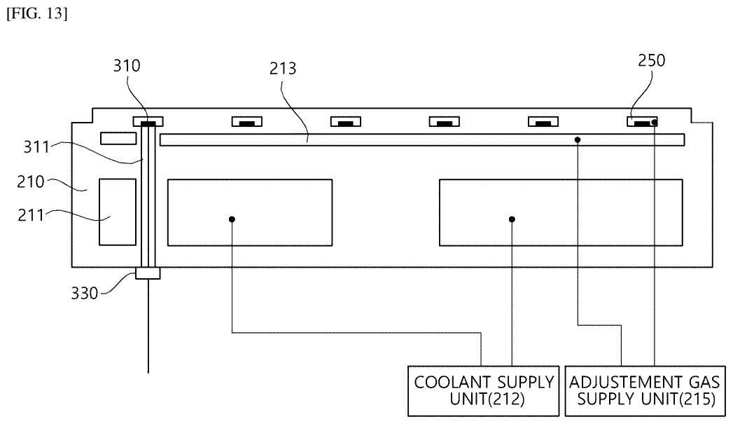

FIG. 13 illustrates a cross-sectional configuration of a body unit when an FBG temperature sensor is installed in a body unit of an electrostatic chuck.

As illustrated in FIG. 13, the FBG temperature sensor 310 may be formed in the hollow 250 formed above the thermal conductivity adjustment channel 213 of the body unit 210.

The FBG temperature sensor 310 is also installed in the hollow 250 of the body unit 210 by the structure which has been described above with reference to FIGS. 6 to 9.

The hollow 250 is filled with thermal conductive paste or epoxy to increase the thermal conductivity of the hollow 250.

Further, the thermal conductivity of the hollow 250 may be increased by the pressure (for example, 100 Torr, 300 Torr, or 760 Torr) formed by injecting the thermal conductivity adjustment gas (for example, He or N₂) into the hollow 250 through the adjustment gas supply unit 215.

The hollow 250 may maintain air-tight state when the thermal conductivity adjustment gas is injected by the feed-through 330 connected to the lower portion of the body unit 210. The optical fiber 311 of the FBG temperature sensor 310 is connected to the outside of the body unit 210 through the feed-through 330 below the body unit 210.

The substrate processing apparatus 100 according to the exemplary embodiments of the present disclosure measures the temperature and the temperature uniformity of the substrate 600 and the focus ring by the FBG temperature sensor 210 installed in the substrate holder 210->220 or the body unit 210 and the focus ring 150.

When the temperature uniformity of the substrate 600 and the focus ring 150 measured by the temperature sensor and the control module (for example, a PID controller) is lower than a reference value, the temperature measurement system (not illustrated) adjusts an output power of the power supply unit 222, a gas flow rate of the adjustment gas supply unit 214, a supplied coolant temperature and a coolant flow rate of the coolant supply unit 212 to improve the temperature uniformity.

In the case of the electrostatic chuck in which the heater electrode 221, the thermal conductivity adjustment channel 213 or the coolant channel 211 is configured by multi zones, a temperature value of an individual zone is measured by the temperature measurement system to adjust an output power of the power supply unit 222 connected to the individual zone, a gas flow rate of the adjustment gas supply unit 214, a supplied coolant temperature and a coolant flow rate of the coolant supply unit 212 to precisely control the temperature uniformity of the substrate 600 and the focus ring 150.

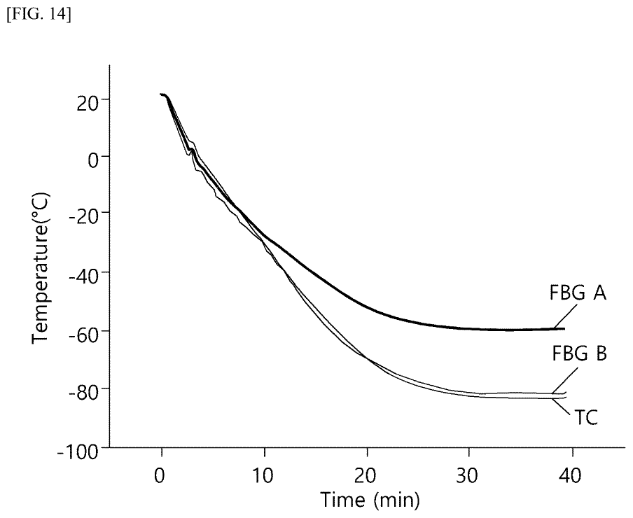

FIG. 14 is a graph obtained by comparing a measurement temperature of an FBG temperature sensor and a measurement temperature of a TC temperature sensor.

FBG A represents a measurement result when a thermal conductive paste is not filled in the hollow, FBG B represents a measurement result when a thermal conductive paste is filled in the hollow, and TC represents a measurement result when an attached type TC temperature sensor is attached in the same position as the FBG temperature sensor.

In the vacuum state, since heat transfer by the conduction is a key point, if there is no sufficient contact between the temperature sensor and an object whose temperature is to be measured, the heat transfer does not properly occur. FBG B is data obtained by measuring a chuck temperature when the thermal conductive paste is filled in the hollow to be brought into contact with the electrostatic chuck and FBG A is data obtained by measuring a chuck temperature when the thermal conductive paste is not filled so that the contact with the electrostatic chuck is not sufficient as compared with FBG B. As a result of comparing with the attached type TC temperature sensor, in FBG B in which the sufficient contact with the electrostatic chuck occurs by the thermal conductive paste, a measurement value is more similar to the measurement value of the attached type TC temperature sensor. Accordingly, when the FBG temperature sensor is installed in the electrostatic chuck, the thermal conductive paste, the epoxy, or the thermal conductivity adjustment gas is used to increase the thermal conductivity, thereby more precisely measuring the temperature.

The above description illustrates a technical spirit of the present invention as an example and various changes, modifications, and substitutions become apparent to those skilled in the art within a scope of an essential characteristic of the present invention. Therefore, as is evident from the foregoing description, the exemplary embodiments and accompanying drawings disclosed in the present disclosure do not limit the technical spirit of the present disclosure and the scope of the technical spirit is not limited by the exemplary embodiments and accompanying drawings. The protective scope of the present disclosure should be construed based on the following claims, and all the technical concepts in the equivalent scope thereof should be construed as falling within the scope of the present disclosure.

What is claimed is:

1. A substrate processing apparatus including a temperature sensor, comprising:
a substrate holder which fixes a substrate by an electrostatic force; and
a body unit which is disposed below the substrate holder and includes a thermal conductivity adjustment channel which adjusts a thermal conductivity based on a pressure formed by a thermal conductivity adjustment gas,
wherein a fiber Bragg grating (FBG) temperature is installed in the substrate holder and the FBG temperature sensor is installed in a hollow formed in the substrate holder.

2. The substrate processing apparatus according to claim 1, wherein a width and a height of the hollow are formed to be larger than a diameter of the FBG temperature sensor.

3. The substrate processing apparatus according to claim 2, wherein the FBG temperature sensor is installed so as to be in contact with at least one inner surface of the hollow.

4. The substrate processing apparatus according to claim 2, wherein a cross-section of the hollow includes a V-shaped groove and the FBG temperature sensor is installed so as to be in contact with both inclined surfaces of the V-shaped groove.

5. The substrate processing apparatus according to claim 2, wherein an end portion of the FBG temperature sensor is fixed to a bottom surface of the hollow and the FBG temperature sensor is installed to be curved in the hollow and a measurement part of the FBG temperature sensor is installed to be in contact with a top surface of the hollow.

6. The substrate processing apparatus according to claim 2, wherein a thermal conductive paste or epoxy is filled in the hollow.

7. The substrate processing apparatus according to claim 2, wherein a thermal conductivity adjustment gas is injected into the hollow.

8. The substrate processing apparatus according to claim 2, further comprising:
a focus ring disposed on an outer periphery of the substrate holder,
wherein a fiber Bragg grating (FBG) temperature is installed in the focus ring and the FBG temperature sensor is installed in a hollow formed in the focus ring.

9. The substrate processing apparatus according to claim 8, wherein the FBG temperature sensor installed in the focus ring is installed at every distance from the substrate.

10. A substrate processing apparatus including a temperature sensor, comprising:
a substrate holder which fixes a substrate by an electrostatic force; and
a body unit which is disposed below the substrate holder and includes a thermal conductivity adjustment channel which adjusts a thermal conductivity based on a pressure formed by a thermal conductivity adjustment gas,
wherein a fiber Bragg grating (FBG) temperature is installed in the body unit and the FBG temperature sensor is installed in a hollow formed in the body unit.

11. The substrate processing apparatus according to claim 10, wherein a width and a height of the hollow are formed to be larger than a diameter of the FBG temperature sensor.

12. The substrate processing apparatus according to claim 11, wherein the FBG temperature sensor is installed so as to be in contact with at least one inner surface of the hollow.

13. The substrate processing apparatus according to claim 11, wherein a cross-section of the hollow includes a V-shaped groove and the FBG temperature sensor is installed so as to be in contact with both inclined surfaces of the V-shaped groove.

14. The substrate processing apparatus according to claim 11, wherein an end portion of the FBG temperature sensor is fixed to a bottom surface of the hollow and the FBG temperature sensor is installed to be curved in the hollow and a measurement part of the FBG temperature sensor is installed to be in contact with a top surface of the hollow.
